(19) United States
(12) Patent Application Publication
(10) Pub. No.: US 2004/0041254 A1
(43) Pub. Date: Mar. 4, 2004

(54) Packaged microchip

(76) Inventors: Lewis Long, Woburn, MA (US); Kieran Harney, Andover, MA (US)

Correspondence Address: Steven G. Saunders, Bromberg & Sunstein LLP, 125 Summer Street, Boston, MA, 02110-1618, US

(21) Appl. No.: 10/369,776

(22) Filed: Feb. 20, 2003

Related U.S. Application Data
(63) Continuation-in-part of application No. 10/234,215, filed on Sep. 4, 2002.

(51) Int. Cl. H01L 23/15

(52) U.S. Cl. 257/703; 257/729

(57) ABSTRACT

A packaged microchip has an isolator that minimizes stress transmission from its package to its microchip. To that end, the packaged microchip includes a stress sensitive microchip having a bottom surface with a bottom surface area, and a package having an integral isolator. The isolator has a top surface with a top surface area that is smaller than the bottom surface area of the microchip. The microchip bottom surface is coupled to the top surface of the isolator.

### PRIORITY

This patent application claims priority from U.S. patent application Ser. No. 10/234,215, filed Sep. 4, 2002, entitled, “PACKAGED MICROCHIP WITH ISOLATION,” and naming Kieran Harney and Lewis H. Long as inventors, the disclosure of which is incorporated herein, in its entirety, by reference.

### FIELD OF THE INVENTION

The invention generally relates to microchips and, more particularly, the invention relates to packaging techniques for microchips.

### BACKGROUND OF THE INVENTION

Microelectromechanical systems (“MEMS”) are used in a growing number of applications. For example, MEMS currently are implemented as gyroscopes to detect pitch angles of airplanes, and as accelerometers to selectively deploy air bags in automobiles. In simplified terms, such MEMS devices typically have a structure suspended above a substrate, and associated electronics that both senses movement of the suspended structure and delivers the sensed movement data to one or more external devices (e.g., an external computer). The external device processes the sensed data to calculate the property being measured (e.g., pitch angle or acceleration).

The associated electronics, substrate, and movable structure typically are formed on one or more dies (referred to herein simply as a “die”) that are secured within a package. For example, the package, which typically hermetically seals the die, may be produced from ceramic or plastic. The package includes interconnects that permit the electronics to transmit the movement data to the external devices. To secure the die to the package interior, the bottom surface of the die commonly is bonded (e.g., with an adhesive or solder) to an internal surface (e.g., a die attach pad) of the package. Accordingly, substantially all of the area of the bottom die surface is bonded to the internal surface the package.

Problems can arise, however, when the temperatures of the two surfaces change. In particular, because both surfaces typically have different coefficients of thermal expansion, the package can apply a mechanical stress to the substrate of the die. This stress (referred to in the art as “linear stress,” which, in this case, is thermally induced) undesirably can bend or flex the substrate to an unknown curvature. Substrate bending or flexing consequently can affect movement of the die structures and the functioning of the electronics, thus causing the output data representing the property being measured (e.g., acceleration) to be erroneous. In a similar manner, mechanically induced linear or torsional stress applied to the package also can be translated to the die, thus causing the same undesirable effects.

### SUMMARY OF THE INVENTION

In accordance with one aspect of the invention, a packaged microchip has an isolator that minimizes stress transmission from its package to its microchip. To that end, the packaged microchip includes a stress sensitive microchip having a bottom surface with a bottom surface area, and a package having an integral isolator. The isolator has a top surface with a top surface area that is smaller than the bottom surface area of the microchip. The microchip bottom surface is coupled to the top surface of the isolator.

The isolator and package illustratively are formed from the same material. For example, the isolator and package may be formed from aluminum oxide. In other embodiments, the isolator and package are formed from AlN. The package may have an inner cavity with a bottom surface and the microchip may be spaced from the bottom surface of the inner cavity. Of course, the package may be one of a cavity-type package and a flat-type package. In some embodiments, the package and isolator have a first coefficient of thermal expansion (“CTE”), and the microchip has a second CTE. The first and second coefficients of thermal expansion thus may be substantially the same.

In accordance with another aspect of the invention, a packaged microchip has a stress sensitive microchip having a microchip CTE, and a package having a package CTE. In addition, the packaged microchip also includes an isolator having an isolator CTE. The isolator is coupled between the stress sensitive microchip and the package. The isolator CTE is within a CTE matched range, where the CTE matched range has a first endpoint that is greater than the microchip CTE, and a second endpoint that is less than the microchip CTE. The first and second endpoints are an equal distance from the microchip CTE. The equal distance is the absolute value of the difference between the package CTE and the microchip CTE.

In some embodiments, the isolator is integral with the package. For example, the package may be formed from aluminum oxide or aluminum nitride.

In accordance with still another aspect of the invention, a packaged microchip includes a stress sensitive microchip having 1) a bottom surface with a bottom surface area and 2) a package having an integral apparatus for reducing stress transmission from the package to the microchip. The integral apparatus has a top surface with a top surface area that is smaller than the bottom surface area of the microchip. The microchip bottom surface is coupled to the top surface of the integral apparatus.

### BRIEF DESCRIPTION OF THE DRAWINGS

The foregoing and advantages of the invention will be appreciated more fully from the following further description thereof with reference to the accompanying drawings wherein:

FIG. 1 schematically shows a partially cut-away view of a packaged microchip that may be produced in accordance with illustrative embodiments of the invention.

FIG. 2 schematically shows a cross-sectional view of one embodiment of the packaged microchip shown in FIG. 1 along line X-X.

FIG. 3 shows a process of producing the packaged microchip shown in FIGS. 1 and 2.

FIG. 4 schematically shows a cross-sectional view of another embodiment of the packaged microchip shown in FIG. 1 along line X-X.

### DESCRIPTION OF ILLUSTRATIVE EMBODIMENTS

In illustrative embodiments of the invention, a packaged microchip (e.g., a microelectromechanical system, also referred to herein as a “MEMS”) includes an isolator that secures a microchip within the interior of a package. The material and/or dimensions of the isolator are selected to minimize microchip stress (e.g., linear stress and torsional stress) caused by the package. In illustrative embodiments, the isolator is integrated into the package, thus eliminating the need to bond the isolator to the package. Details of these and other embodiments are discussed below.

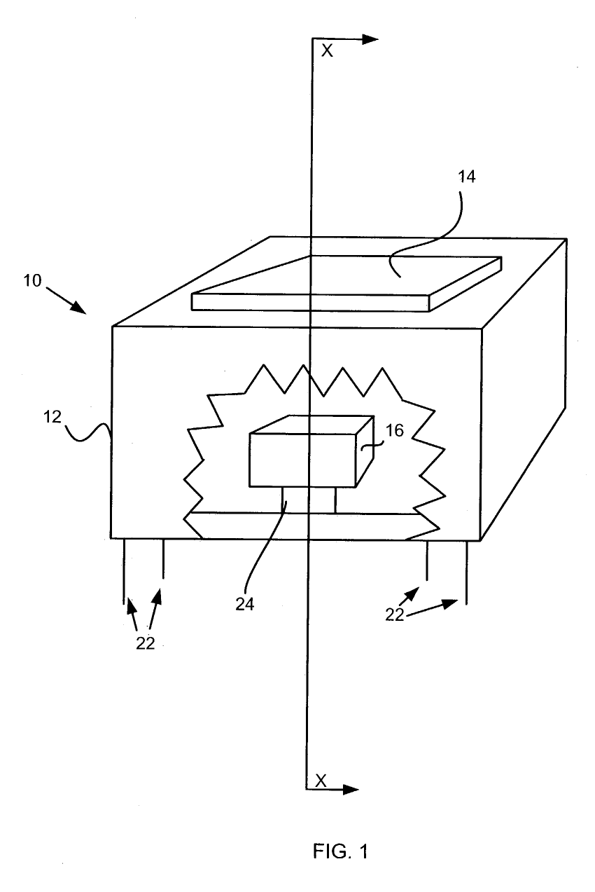

FIG. 1 schematically shows a partially cut-away isometric view of a packaged microchip 10 that can implement various embodiments of the invention. In illustrative embodiments, the packaged microchip 10 is a MEMS device implemented as a gyroscope. Accordingly, for illustrative purposes, various embodiments are discussed herein as a MEMS gyroscope. The MEMS device shown in FIGS. 1, 2, and 4 thus are identified as gyroscope 10. It should be noted, however, that discussion of various embodiments as a MEMS gyroscope is exemplary only and thus, not intended to limit all embodiments of the invention. Accordingly, some embodiments may apply to other types of microchip devices, such as integrated circuits. In addition, embodiments of the invention can be applied to other types of MEMS devices, such as MEMS-based optical switching devices and MEMS-based accelerometers. In addition, embodiments of the invention can be applied to microchip devices mounted in packages that are not hermetically sealed, such as cavity plastic packages and the like.

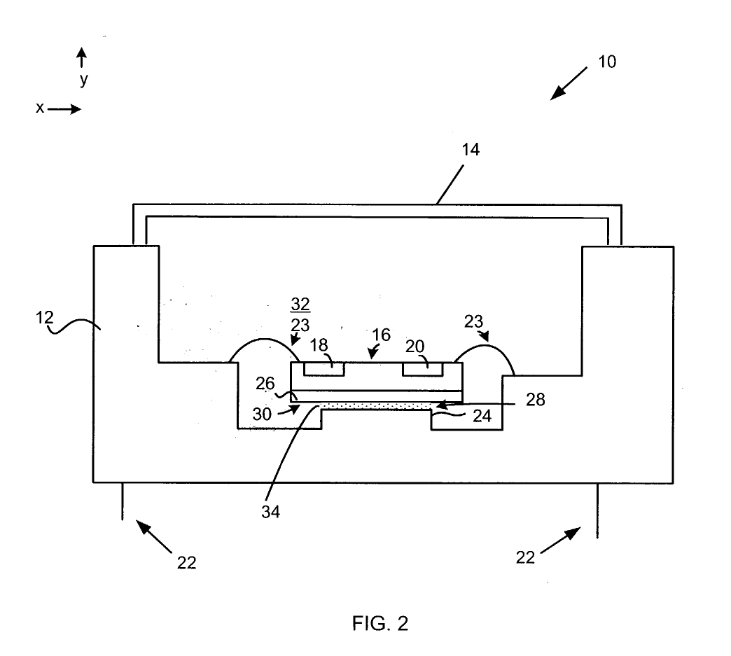

The gyroscope 10 shown in FIG. 1 includes a conventional package 12, a lid 14 to hermetically seal the package 12, and a conventional gyroscope die 16 secured within the sealed interior 32. The gyroscope die 16 includes the well known mechanical structure and electronics (discussed below with regard to FIG. 2) that measure angular rate in a given axis. A plurality of pins 22 extending from the package 12 electrically connect with the gyroscope die 16 to permit electrical communication between the gyroscope electronics and an exterior device (e.g., a computer).

Rather than being directly bonded to the interior surface of the package 12, the gyroscope die 16 is bonded to an isolator 24 that is integrated into the package 12. In other words, the isolator 24 illustratively is produced (e.g., stamped) from the same piece of material as that used to form the package 12. More specifically, FIG. 2 schematically shows a cross-sectional view of the packaged microchip 10 shown in FIG. 1 along line X-X. This view clearly shows the package 12 and its corresponding lid 14, the die 16, and the isolator 24.

As noted above, the die 16 includes conventional silicon MEMS structure 18 to mechanically sense angular rotation, and accompanying electronics 20. Such structure 18 and electronics 20 (both shown schematically in FIG. 2) illustratively are formed on a silicon-on-insulator wafer, which has an oxide layer between a pair of silicon layers. As an example, among other things, the MEMS structure 18 may include one or more vibrating masses suspended above a silicon substrate 26 by a plurality of flexures. The structure 18 also may include a comb drive and sensing apparatus to both drive the vibrating masses and sense their motion. Accordingly, the electronics 20 may include, among other things, the driving and sensing electronics that couple with the comb drive and sensing apparatus, and signal transmission circuitry. Wires 23 electrically connect the accompanying electronics 20 with the pins 22. Exemplary MEMS gyroscopes are discussed in greater detail in co-pending provisional U.S. patent applications identified by serial Nos. 60/364,322 and 60/354,610, both of which are assigned to Analog Devices, Inc. of Norwood, Mass. The disclosures of both of the noted provisional patents are incorporated herein, in their entireties, by reference.

In alternative embodiments, the MEMS structure 18 and accompanying electronics 20 are on different dies. For example, the die 16 having the MEMS structure 18 may be mounted to the package 12 by a first isolator 24, while the die 16 having the accompanying electronics 20 may be mounted to the package 12 by a second isolator 24. Alternatively, both dies may be mounted to the same isolator 24. In some cases, one of the dies 16 (i.e., a stress sensitive die 16) may be mounted on the isolator 24, while the other die 16 (i.e., a non-stress sensitive die 16) may be mounted directly to the package 12. It should be noted, however, that principles of illustrative embodiments apply to such embodiments.

The die 16, which is a microchip and/or integrated circuit, is sensitive to either or both linear and torsional stress. In this context, the term “sensitive” generally means that the operation of the structure 18 and/or electronics 20 on the die 16 can be compromised when subjected to stress. For example, as suggested above, stress applied to the die 16 can cause the flexures suspending the mass to bend or compress. As a consequence, the mass may not vibrate at a prescribed rate and angle, thus producing a quadrature problem. As a further example, the comb drive may become misaligned, or the electronics 20 may become damaged. Any of these exemplary problems undesirably can corrupt the resulting data produced by the MEMS die 16. Accordingly, for these reasons, the die 16 or other microchip may be referred to as being “stress sensitive.”

To mitigate these stress related problems, in illustrative embodiments, the bonding surfaces of the isolator 24 and the die 16 are sized to minimize direct contact. Specifically, the isolator 24 has a top surface 28 that is bonded to the bottom surface 30 of the die 16. The isolator top surface 28 has a surface area that is smaller than that of the bottom surface 30 of the die 16, thus forming a space between the die bottom surface 30 and the internal surface of the package 12. Accordingly, a relatively large portion of the die bottom surface 30 is not subjected to direct torsional stress produced by the package 12.

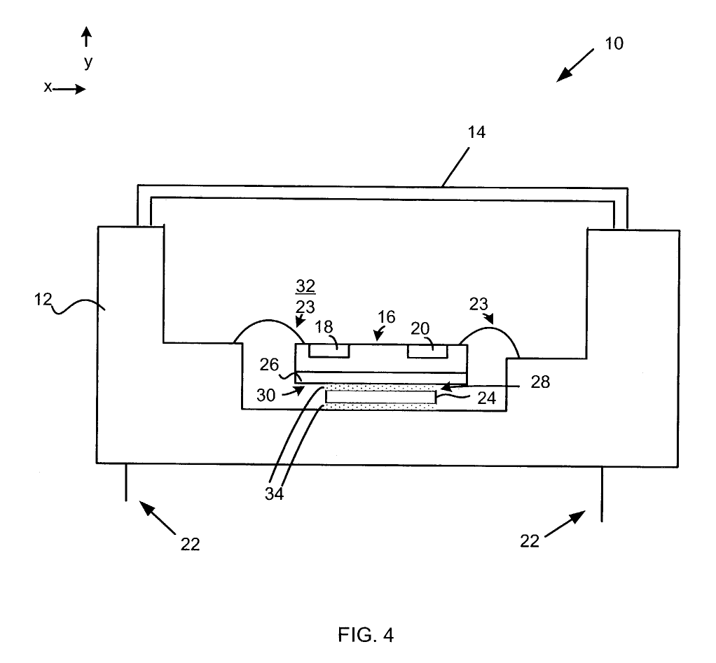

The noted space formed between the die bottom surface 30 and internal surface of the package 12 may be formed in a number of ways. For example, the isolator 24 may elevate the die 16 some distance above the internal surface of the package 12 (shown in FIGS. 2 and 4). As a further example, the inner surface of the package 12 may be contoured to effectively form the isolator 24. In such case, the isolator 24 may have walls extending into a recess formed by the interior surface of the package 12.

The process of selecting the relative sizes of the isolator 24 and die 16 in the manner discussed herein is referred to as “matching.” Qualitatively, their relative dimensions should be selected so that the isolator 24 has a minimum surface area that sufficiently supports the die 16. If the size of the isolator 24 is too small relative to the die 16, the die 16 may tilt, or its ends may droop downwardly.

Exemplary dimensions of the various components of the packaged die 16 thus follow. Note that on FIG. 2, the X direction indicates length, the Y direction indicates height (thickness), and the Z direction (i.e., not shown but perpendicular to the X and Y directions) indicates width.

Package 12: Height: 0.12 inches;

Die 16: Length: 0.170 inches; Width: 0.140 inches; Height: 0.027 inches;

Isolator 24: Length: 0.040 inches; Width: 0.040 inches; Height: 0.026 inches.

A packaged microchip having these relative dimensions should perform satisfactorily for the purposes described herein. Of course, these dimensions are for illustration only. Other embodiments thus are not limited to these specific dimensions. Accordingly, a packaged microchip 10 having an isolator 24, package 12, and die 16 with different dimensions, within the noted constraints, should provide a corresponding stress attenuation.

In illustrative embodiments, an adhesive 34 bonds the isolator 24 to the die bottom surface 30. Such adhesive 34 preferably also has stress absorbing properties, thus further attenuating the noted stresses. In exemplary embodiments, the adhesive 34 is a silver filled glass adhesive material, such as Dexter product code number QMI3555, distributed by Dexter Electronic Materials of San Diego, Calif. Dexter Electronic Materials is a division of Loctite Corporation of Germany.

Other types of material may be used to bond the isolator 24 to the die 16 and the package 12. Such materials include other silver glass materials, epoxies, cynate esters, and silicone. A high temperature organic adhesive, such as Siloxane, also should produce satisfactory results. Although desirable, in various embodiments, it is not necessary that these bonding agents have stress absorbing properties. In addition, other conventional means may be used to connect the isolator 24 to both the die 16 and the package 12. Accordingly, discussion of adhesive 34 is exemplary and not intended to limit the scope of various embodiments of the invention.

It should be noted that discussion of a cavity-type package 12 is for specific embodiments only. Various other embodiments, however, can be implemented with other types of packages 12. For example, the packaged microchip 10 may use a flat-type package 12, in which a lid 14 or other apparatus seals around the die 16 to effectively form the interior of the overall device. Accordingly, many embodiments should not be limited to cavity-type packages 12.

In addition to (or instead of) matching the relative sizes of the die 16 and isolator 24, some embodiments also match the isolator material to that of the die 16. More specifically, the isolator 24 may be formed from a material having a coefficient of thermal expansion (“CTE”) that matches that of the die 16. In other words, in illustrative embodiments, the CTE of the isolator 24 is substantially the same as that of the die 16. For example, if the die 16 is produced from silicon, then the isolator 24 and the remainder of the package 12 may be manufactured from aluminum nitride (AlN), which has a CTE that is substantially the same as that of silicon. In other embodiments, if the die 16 is produced from silicon, then the isolator 24 and the remainder of the package 12 may be manufactured from aluminum oxide (also known as “alumina” and identified by the formula Al₂O₃), which has a CTE that, compared to that of aluminum nitride, is not as close to that of silicon. When produced from aluminum oxide, however, it is preferable that the relative dimensions of the die 16 bottom surface match that of the isolator 24 top surface (as discussed above).

As noted above, the isolator 24 and package 12 illustratively are the same material in those embodiments in which the isolator 24 is integral with the package 12. In alternative embodiments, however, it is contemplated that a composite material can be produced in which the isolator 24 has a different CTE than that of the package 12, while still being integral with the package 12. In this alternative embodiment, the isolator 24 may be produced from a material that is different than that of the remainder of the package 12.

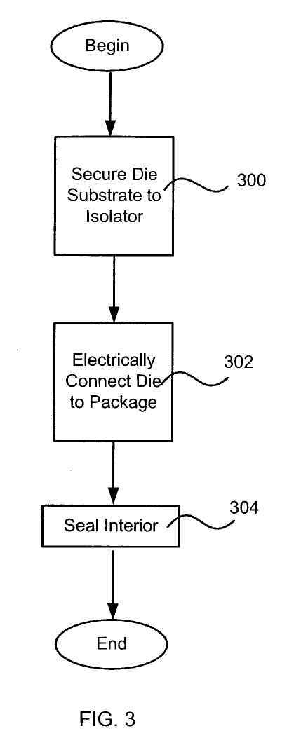

FIG. 3 shows an exemplary process of assembling the packaged microchip 10 shown in FIGS. 1 and 2. The process begins at step 302, in which the bottom surface 30 of the substrate 26 is bonded to the top surface 28 of the isolator 24. The die 16 then is electrically interconnected to the package 12 (step 302). Next, at step 304, the lid 14 is secured to the top of the package 12, thus sealing the interior 32. If desired, a gas may be injected into the package interior 32 before the lid 14 is secured to the package 12.

In some embodiments, the isolator 24 is not integral with the package 12. Specifically, as shown in FIG. 4, the isolator 24 is a separate component from the package 12. In such embodiments, the isolator 24 may be produced from a material that is either the same as, or different than, the material used to produce the package 12. For example, the isolator 24 may be produced from a material with a CTE that is matched to that of the die 16. Because it is a separate component, the isolator 24 may be coupled to the package 12 in any manner known in the art, such as with an adhesive as discussed above. For additional details regarding this embodiment, see above noted U.S. patent application Ser. No. 10/234,215.

To mitigate stress in this and related embodiments, it is desirable for the isolator 24 to have a CTE that is within a range around the CTE of the die 16. This range has boundaries that are a calculated amount greater and less than the CTE of the die. The calculated amount is defined as the absolute value of the difference between the CTE of the die 16 and the CTE of the package 12. This range is referred to herein as the “CTE matched range.”

For example, if the die 16 is produced from silicon (which has a CTE of 4 ppm per degree Celsius) and the package 12 is produced from aluminum oxide (which has a CTE of about 7 ppm per degree Celsius), then the isolator 24 illustratively is produced from a material having a CTE between about 1 ppm per degree Celsius and about 7 ppm per degree Celsius. In such case, although better results are expected to be when the isolator 24 is produced from a material having a CTE of about 4 ppm per degree Celsius, improved results (vs. than using an isolator material that is the same as that of the package 12) should occur if its CTE is within the noted range.

As a further example, if the CTE of the package material is equal to that of the die material, then the CTE matched range effectively is zero. In such case, if the isolator material has a CTE that is the same as that of the die material, then it is considered to be within the CTE matched range. As discussed above, improved results also are expected when the sizes of the isolator 24 and die 16 are matched.

Although various exemplary embodiments of the invention are disclosed below, it should be apparent to those skilled in the art that various changes and modifications can be made that will achieve some of the advantages of the invention without departing from the true scope of the invention.

What is claimed is:

1. A packaged microchip comprising:
a stress sensitive microchip having a bottom surface with a bottom surface area;
a package having an integral isolator, the isolator having a top surface with a top surface area that is smaller than the bottom surface area of the microchip,
the microchip bottom surface being coupled to the top surface of the isolator.

2. The packaged microchip as defined by claim 1 wherein the isolator and package are formed from the same material.

3. The packaged microchip as defined by claim 2 wherein the isolator and package are formed from aluminum oxide.

4. The packaged microchip as defined by claim 2 wherein the isolator and package are formed from aluminum nitride.

5. The packaged microchip as defined by claim 1 wherein the package has an inner cavity with a bottom surface, the microchip being spaced from the bottom surface of the inner cavity.

6. The packaged microchip as defined by claim 1 wherein the package and isolator have a first CTE, the microchip having a second CTE, the first and second coefficients of thermal expansion being substantially the same.

7. The packaged microchip as defined by claim 1 wherein the package is one of a cavity-type package and a flat-type package.

8. A packaged microchip comprising:
a stress sensitive microchip having a microchip CTE;
a package having a package CTE; and
an isolator having an isolator CTE, the isolator being coupled between the stress sensitive microchip and the package,
the isolator CTE being within a CTE matched range, the CTE matched range having a first endpoint that is greater than the microchip CTE, the CTE matched range having a second endpoint that is less than the microchip CTE, the first and second endpoints being an equal distance from the microchip CTE, the equal distance being the absolute value of the difference between the package CTE and the microchip CTE.

9. The packaged microchip as defined by claim 8 wherein the isolator is integral with the package.

10. The packaged microchip as defined by claim 9 wherein the package is formed from aluminum oxide.

11. The packaged microchip as defined by claim 9 wherein the package is formed from aluminum nitride.

12. The packaged microchip as defined by claim 8 wherein the package has an inner cavity with a bottom surface, the microchip being spaced from the bottom surface.

13. The packaged microchip as defined by claim 8 wherein the microchip has a bottom surface with a bottom surface area, the isolator having a top surface with a top surface area, the bottom surface of the microchip being coupled with the top surface of the isolator, the bottom surface area being greater than the top surface area.

14. A packaged microchip comprising:
a stress sensitive microchip having a bottom surface with a bottom surface area;
a package having integral means for reducing stress transmission from the package to the microchip, the reducing means having a top surface with a top surface area that is smaller than the bottom surface area of the microchip,
the microchip bottom surface being coupled to the top surface of the reducing means.

15. The packaged microchip as defined by claim 14 wherein the reducing means includes an isolator.

16. The packaged microchip as defined by claim 14 wherein the reducing means and package are formed from the same material.

17. The packaged microchip as defined by claim 14 wherein the microchip is a MEMS device.

18. The packaged microchip as defined by claim 14 wherein the package has an inner cavity with a bottom surface, the microchip being spaced from the bottom surface of the inner cavity.

19. The packaged microchip as defined by claim 14 wherein the package is one of a cavity-type package and a flat-type package.

20. The packaged microchip as defined by claim 14 wherein the package and reducing means have a first CTE, the microchip having a second CTE, the first and second coefficients of thermal expansion being substantially the same.
